(19) United States
(12) Patent Application Publication
(10) Pub. No.: US 2024/0154333 A1
(43) Pub. Date: May 9, 2024

(54) TRIBOLOGICALLY IMPROVED SURFACES FOR ELECTRICAL CONTACTS

(71) Applicant: Rosenberger Hochfrequenztechnik GmbH & Co. KG, Fridolfing (DE)

(72) Inventors: Reinhard Wagner, Seekirchen am Wallersee (AT); Christian Dandl, Fridolfing (DE)

(21) Appl. No.: 18/281,134

(22) PCT Filed: Mar. 17, 2022
(86) PCT No.: PCT/EP2022/057051

§ 371 Date: Sep. 8, 2023

(30) Foreign Application Priority Data
Mar. 17, 2021 (EP) 21163067.8

(51) Int. Cl. H01R 13/03; C23C 4/06; C23C 14/06; C23C 14/34; C23C 28/00; C25D 5/12; C25D 7/06; H01R 43/16

(52) U.S. Cl. CPC H01R 13/03; C23C 14/0623; C23C 14/34; C23C 28/345; H01R 43/16; C23C 4/06; C25D 5/12; C25D 7/0614

(57) ABSTRACT

The present invention relates to a method for producing an electrical contact, in particular an electrical plug contact, comprising the steps of a) providing a substrate, wherein the substrate has a metallic and/or metallized surface, and b) applying a low-friction surface to the metallic and/or metallized surface of the substrate, wherein the low-friction surface is applied by mechanical rubbing, polishing and/or buffing of a solid lubricant; or wherein the low-friction surface is applied by spray application of a solid lubricant; or wherein the low-friction surface is applied by applying a solid lubricant by means of a drum washer; and wherein the low-friction surface (6) has a film thickness of 0.001 μm-4 μm.

The present invention relates to a method of manufacturing an electrical contact, an electrical contact, and the use of an electrical contact for connectors. In another aspect, the present invention relates to the use of a solid lubricant used in accordance with the invention for adjusting a coefficient of friction of surfaces of electrical contacts.

Electrical contacts have contact surfaces that are usually made of an electrically conductive material, preferably a metallic conductor. Electrical contacts preferably consist of a rigid end and a resilient end that applies the contact force, with both ends usually having a metallic coating that is different from the base material. This coating can be produced, for example, by immersion in a molten metal by physical and/or chemical vapor deposition, or by external currentless or electrolytic coating. Commonly used coating materials include gold, silver, palladium, platinum, rhodium, ruthenium, nickel, tin, copper, zinc, or alloys thereof. By using such coatings, desired properties of the electrical contact surface, such as improved corrosion resistance, improved wear behavior, ensuring stable electrical contact resistance, and/or a reduction in the coefficient of friction can be achieved.

In order to achieve a further improvement of the wear behavior, so-called contact lubricants are often used for electrical contact surfaces. From Chudnovsky (2005; Lubrication of electrical contacts; In Proceedings of the Fifty-First IEEE Holm Conference on Electrical Contacts; 2005; pp. 107-114; IEEE), a number of corresponding contact lubricants are known, with a distinction being made in detail between mineral oils, greases, synthetically produced lubricants based on synthetically produced compounds, such as polyphenyl ether (PPE) and perfluorinated polyether (PFPE), as well as solid lubricants such as graphite, molybdenum disulfide, polytetrafluoroethylene (PTFE) and dispersions of solid lubricants and the liquid/pasty lubricants mentioned.

However, it has been shown that the mere lubrication of electrical contact surfaces by means of the solid lubricants mentioned leads to a deterioration in electrical conductivity, which in turn results in a high increase in electrical contact resistance, is undesirable, so that there is still a need for improved electrical contact surfaces or electrical contacts.

DE2543082A1 describes a silver-graphite dispersion coating in which graphite is incorporated as a solid lubricant in a metal matrix by means of electrodeposition. A disadvantage of this process is the lack of flexibility due to the restriction to certain electrolyte compositions and the metals that can be deposited by means of electrodeposition.

From Berman et al (Berman, D.; Erdemir, A.; Sumant, A. V.; 2014; Graphene as a protective coating and superior lubricant for electrical contacts; Appl. Phys. Lett. 105, 231907 (2014); DOI: 10.1063/1.4903933), another coating for electrical contacts is known. The coating comprises graphene, resulting in an improvement of tribological properties by reducing the coefficient of friction as well as a reduction of wear. To produce the coating, graphene particles are deposited on a gold substrate by dropping a graphene-ethanol suspension with a graphene content of 1 mg/mL onto the gold surface and then evaporating the solvent. The resulting surface has a coverage of about 50%. However, the resulting contact resistance of these coatings, with a value of 100 ohms, is too high for numerous applications as electrical contact surfaces. In addition, the production of this coating is very complex and cost-intensive.

From U.S. Pat. No. 3,644,133 A, a process for the preparation of solid lubricant-based coatings is known. The solid lubricant used here has a layer-like crystal structure. Furthermore, a lubricant formed from transition metal dichalcogenides and polymers is known from U.S. Pat. No. 5,407,590 A and WO 96/20083 A1 respectively.

Against this background, it is the object of the present invention to provide a method for manufacturing an electrical contact and electrical contact that has an advantageous coefficient of friction, high wear resistance and good contact resistance. The method is also intended to be time-saving and cost-effective.

### DESCRIPTION OF THE INVENTION

According to the invention, the object is solved by a method for producing an electrical contact according to patent claim 1, an electrical contact according to claim 6, the use of an electrical contact according to claim 17, and the use of a solid lubricant according to claim 18.

In a first aspect, the invention relates to a method for manufacturing an electrical contact, in particular a plug-in electrical contact (1), comprising, preferably consisting of, the steps of
a) providing a substrate (2), the substrate having a metallic and/or metallized surface, and
b) applying a sliding layer on the metallic and/or metallized surface of the substrate (2),
   wherein the sliding layer (6) is formed by mechanical rubbing, polishing and/or buffing a solid lubricant; or
   wherein the sliding layer (6) is applied by sputtering a solid lubricant; or
   wherein the sliding layer (6) is applied by spraying a solid lubricant using a carrier gas; or
   wherein the sliding layer (6) is formed by applying a solid lubricant by means of a drum washer, preferably in the presence of packing; and wherein the sliding layer (6) has a layer thickness of 0.001 μm-4 μm.

Surprisingly, it has been shown that the tribological properties of an electrical contact can be significantly improved by mechanically applying, sputtering, spraying or applying by means of drum washers a sliding layer to a substrate which has a metallic and/or metallized surface, without having a significant negative effect on the electrical properties, in particular the contact resistance. The tribological properties, which are improved compared with the prior art, simultaneously lead to a reduction in wear, so that in particular the electrical contacts according to the invention, if they are used for plug contacts, can withstand higher mating cycles with simultaneously stable contact resistance values.

In the method according to the invention, there is no chemical reaction of the surface of the substrate or any other surface layer, such as an intermediate layer, to produce the solid lubricant or solid lubricant particles on the surface.

Furthermore, depending on the solid lubricant used, the application process can be carried out in a particularly simple manner so that, for example, auxiliary agents such as binders and similar materials are not required, which has a particularly advantageous effect on the costs of the process according to the invention.

Furthermore, it has been surprisingly shown that the electrical contacts according to the invention, in addition to the advantages already explained, have an increased temperature resistance, so that use at higher temperatures and/or under vacuum of these and/or the electrical contacts made from them is possible. In addition, the electrical contacts withstand high contact pressures without losing the positive tribological properties.

Further advantageous embodiments of the invention are given in the dependent claims. The features listed individually in the dependent claims can be combined with each other in a technologically useful manner and can define further embodiments of the invention. In addition, the features indicated in the claims are further specified and explained in the description, wherein further preferred embodiments of the invention are illustrated.

For the purposes of the present invention, the term “solid lubricant” is understood to mean a lubricant which is present in a solid aggregate state and is used in this state.

For the purposes of the present invention, the term “buffing” is understood to mean the application of solid lubricant particles by oscillating or rotating movements of a buffing wheel, which consists of sewn textile fabric discs, or a buffing brush, or similar devices, which can temporarily pick up the particles and apply them mechanically to the surface while moving.

For the purposes of the present invention, the term “mean particle size (d50)” indicates that 50% of the particles of a solid constituent have a smaller diameter than the specified value. The d90 value indicates that 90% of the particles of a solid constituent have a smaller diameter than the specified value.

For the purposes of the present invention, the term “metallic surface” is understood to mean a surface of a metallic substrate. In this context, the substrate may consist of a pure metal or an alloy.

For the purposes of the present invention, the term “metallized surface” is understood to mean a metal-containing surface that is applied directly to a substrate, in particular a non-metal substrate. In particular, the surfaces of electrically non-conductive materials such as plastics, glass, oxides, semiconductors or ceramics are metallized. Such surfaces are, for example, nickel-plated, galvanized, tin-plated, copper-plated, chromium-plated or coated with other materials, such as with aluminum and magnesium alloys, iron, steel, or technical alloys of these metals, or also with precious metals, such as gold or silver or their alloys. Preferred alloys for coating substrate surfaces are copper, zinc, alloys of zinc/iron, zinc/manganese, zinc/cobalt or tin, alloys of tin/copper, tin/zinc, tin/lead, tin/silver, tin/bismuth. Various metallization processes are known, for example, from DE 10 2016222943 B.

For the purposes of the present invention, the term “intermediate layer” refers to a layer which is disposed on a substrate, wherein a further metal layer or several further metal layers may be disposed between the substrate and the intermediate layer. The sliding layer, if present, is applied to the intermediate layer.

For the purposes of the present invention, the term “sliding layer” refers to a layer consisting of or containing a solid lubricant, which is arranged on a substrate or an intermediate layer and has tribologically advantageous properties. A sliding layer within the meaning of the present invention is not produced by electrochemical deposition, in particular electroplating of a surface. The tribologically advantageous properties may result, for example, from a low coefficient of friction p or a reduction in wear compared to surfaces without a sliding layer. Preferably, the solid lubricant is applied in particulate form. The sliding layer can be closed, i.e. the solid lubricant completely covers the underlying substrate or the intermediate layer, or not closed, i.e. the solid lubricant does not completely cover the underlying substrate or the intermediate layer, but for example in the form of isolated solid lubricant particles and/or in the form of coherent solid lubricant particles, the underlying substrate or the intermediate layer still being at least partially exposed and not covered by solid lubricant.

The sliding layer of the electrical contact must not exceed a maximum layer thickness, as this can have a negative effect on the contact resistance. The layer thickness can be determined (mathematically) from EDX-REM (energy dispersive X-ray spectroscopy-scanning electron microscopy) measurements. Other methods for layer thickness determination are, for example, XRF (X-ray fluorescence spectroscopy) or LA-ICP-MS (laser-ablation-inductively coupled plasma mass spectrometry). Preferably, the sliding layer has a layer thickness of at most 3 μm, preferably a layer thickness of at most 2 μm, more preferably a layer thickness of at most 1 μm and even more preferably 0.01 μm-1 μm. The layer thickness is at least 0.001 μm, preferably at least 0.01 μm, more preferably at least 0.05 μm and even more preferably at least 0.1 μm. In a very particularly advantageous embodiment, the layer thickness of the sliding layer is from 1 nm to 500 nm, preferably from 10 nm to 500 nm, more preferably from 50 nm to 500 nm and even more preferably from 100 nm to 500 nm.

In an advantageous embodiment, the average particle size (d50) of the solid lubricant is from 1 nm-100 μm, preferably from 50 nm-75 μm, more preferably from 100 nm-50 μm, even more preferably from 500 nm-35 μm, and even more preferably from 1 μm-20 μm.

The particles of the solid lubricant are regularly not isometric, i.e. spherical, but platelet-shaped. The mean particle size (d50) here corresponds to the particle diameter, i.e. the longer axis of the particle, and not to the particle thickness, which is regularly smaller than the diameter. Due to the orientation of the particles during application, the thickness of the sliding layer therefore regularly corresponds to the particle thickness. Preferably, the particle thickness of the solid lubricant is from 1 nm-4 μm, more preferably 10 nm-4 μm, even more preferably from 100 nm-4 μm and even more preferably from 100 nm to 3 μm.

Preferably, no binder and/or solvent is used in step b). Further preferably, no lubricant additive is used in step b).

Preferably, in step b) the solid lubricant is applied in particulate form. Thus, step b) involves the application of a solid lubricant layer, also referred to as a sliding layer, with the solid lubricant being used in particulate form.

The layer thickness of the sliding layer corresponds to a single or multiple of the thickness of the solid lubricant particles. In a preferred embodiment, the layer thickness of the sliding layer corresponds to the single thickness of the solid lubricant particles, the sliding layer being formed from a monolayer of solid lubricant particles. This monolayer of solid lubricant particles can be closed, i.e. the solid lubricant completely covers the underlying substrate or the intermediate layer, or not closed, i.e. the solid lubricant does not completely cover the underlying substrate or the intermediate layer but, for example, in the form of isolated solid lubricant particles and/or in the form of coherent solid lubricant particles, the underlying substrate or the intermediate layer still being at least partially exposed and not covered by solid lubricant.

All conventional substrates, in particular metallic substrates, can be used to manufacture the electrical contacts according to the invention.

According to a preferred embodiment, the substrate is a metallic substrate. Preferably, the metallic substrate is formed of copper, iron, zinc, tin, aluminum, and/or alloys thereof. Preferably, alloys are bronze or brass. More preferably, the metallic substrate is formed of copper, iron, and/or alloys thereof.

According to another preferred embodiment, the substrate is a non-metallic substrate. Preferably, the non-metallic substrate is formed of plastics, glass, oxides, semiconductors and/or ceramics, more preferably the non-metallic substrate is formed of plastics or ceramics. Preferably, the non-metallic substrate has a metallized surface.

In a preferred embodiment, the substrate has an intermediate layer. In this embodiment, the sliding layer is applied to the intermediate layer.

In another preferred embodiment, the intermediate layer is formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn), and/or an alloy thereof.

Preferably, the intermediate layer is a tin or silver layer.

Preferably, the intermediate layer is applied by electroplating, by immersion in a metallic melt, thermal spray processes, physical vapor deposition processes, by hot-dip tinning, or chemical vapor deposition processes. Thermal spray processes include flame spraying, laser spraying, plasma spraying, and other related processes. More preferably, the intermediate layer is applied by electroplating or hot-dip tinning. Further preferably, the intermediate layer is applied by means of external-currentless processes. Processes without external current are known from the prior art.

In another preferred embodiment, the substrate has an intermediate layer and at least one further metal layer, wherein the at least one further metal layer is arranged between the substrate and the intermediate layer, wherein the at least one further metal layer is preferably formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof. The sliding layer is applied to the intermediate layer.

According to a further preferred embodiment, the substrate comprises an intermediate layer and at least two further metal layers, wherein the at least two further metal layers are arranged between the substrate and the intermediate layer, wherein the at least two further metal layers are preferably formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof. The sliding layer is applied to the intermediate layer.

Alloys can be, for example, Cu—Sn—Zn alloys, preferably white bronze.

In addition to the aforementioned metals, the intermediate layer and the metal layers may also contain up to a proportion of 0.001 to 15% by weight and preferably 0.01 to 10% by weight, based on the total mass of the respective layer, of further inorganic constituents such as phosphorus, boron, antimony, tellurium, cobalt, indium, iron, tungsten or mixtures thereof. Shares of hard metals such as tungsten may also be added.

According to a preferred embodiment, the intermediate layer and the metal layers contain, in addition to the aforementioned metals, 0.01 to 1% by weight and preferably 0.05 to 0.5% by weight, based on the total mass of the respective layer, of further inorganic constituents such as phosphorus, boron, antimony, tellurium, cobalt, indium, iron, tungsten or mixtures thereof.

According to a preferred embodiment, step a) comprises, preferably consists of, the following steps: Providing a substrate and applying an intermediate layer.

According to a further preferred embodiment, step a) comprises, preferably consists of, the following steps: Providing a substrate, applying at least one further metal layer, preferably a further first metal layer and a further second metal layer, and then applying an intermediate layer.

According to another preferred embodiment, step a) comprises, preferably consists of, the following steps: Providing a substrate, applying at least three further metal layers and then applying an intermediate layer.

The metal layers can be applied by electroplating, immersion in a metallic melt, thermal spray processes, physical vapor deposition processes, hot-dip tinning, or chemical vapor deposition processes. Thermal spray processes include flame spraying, laser spraying, plasma spraying and other related processes. More preferably, the intermediate layer is applied by electroplating or hot-dip tinning. Further preferably, the metal layers can be applied by external currentless processes.

In a preferred embodiment, the solid lubricant is selected from the group consisting of sulfides, selenides and/or tellurides. Further preferably, the solid lubricant is selected from the group consisting of WS₂, MoS₂, NbS₂, NbSe₂, TaS₂, MoTe₂, MoSe₂, WTe₂, WSe₂, HfS₂, SnS₂, Bi₂S₃, Sb₂S₃ and/or mixtures thereof.

In another preferred embodiment, the solid lubricant is selected from the group consisting of graphite, graphite oxide, graphite fluoride, phthalocyanine, organic polymers, in particular polytetrafluoroethylene (PTFE) and/or metal complexes derived therefrom.

Coating with the sliding layer can be carried out in different ways. For example, the sliding layer can be applied to the intermediate layer mechanically by rubbing, polishing and/or buffing.

The sliding layer can also be sputtered onto the intermediate layer.

Furthermore, the particulate solid lubricant can be sprayed onto the intermediate layer through a gaseous carrier medium, for example air. The adhesion can be specifically adjusted via the spray parameters, such as pressure.

Furthermore, the sliding layer can be applied to the intermediate layer, if necessary in the presence of packing, via a drum washer or using vibrating vessels.

The present invention also relates to a method for manufacturing an electrical contact, in particular an electrical plug-in contact, comprising the steps of
a) providing a substrate, the substrate having a metallic and/or metallized surface; and
b) applying of a sliding layer to the metallic and/or metallized surface of the substrate,
   wherein the sliding layer is applied by mechanical rubbing, buffing and/or buffing of a solid lubricant; or
   wherein the sliding layer is applied by sputtering a solid lubricant; or
   wherein the sliding layer is applied by spraying a solid lubricant, preferably using a carrier gas; or
   wherein the sliding layer is applied by applying a solid lubricant by means of a drum washer.

The above embodiments and modifications also apply to this process.

In a second aspect, the invention relates to an electrical contact comprising a substrate (2), the substrate (2) having a metallic and/or metallized surface, and at least one sliding layer (6) arranged on the metallic and/or metallized surface of the substrate (2), the sliding layer (6) consisting of a solid lubricant, the sliding layer (6) having a layer thickness of 0.001 μm-4 μm. Preferably, the electrical contact is a plug-in electrical contact.

Preferably, the solid lubricant is in particulate form.

In a preferred embodiment, the substrate has an intermediate layer disposed on the metallic and/or metallized surface of the substrate. The intermediate layer is preferably formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof. The sliding layer is arranged on the intermediate layer.

In another preferred embodiment, the substrate has at least one further metal layer disposed on the metallic and/or metallized surface of the substrate. The at least one further metal layer is preferably formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof. An intermediate layer is disposed on the at least one further metal layer, the intermediate layer preferably being formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof. The sliding layer is arranged on the intermediate layer.

In a further preferred embodiment, the substrate has at least one first further metal layer arranged on the metallic and/or metallized surface of the substrate, the at least one first further metal layer preferably consisting of one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof, wherein a second further metal layer is arranged on the first further metal layer, wherein the at least one second further metal layer is preferably formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and/or an alloy thereof and wherein an intermediate layer is arranged on the at least second further metal layer, the intermediate layer preferably being formed from one of the metals selected from the group comprising gold (Au), copper (Cu), nickel (Ni), palladium (Pd), platinum rhodium (Rh), ruthenium (Ru), silver (Ag), zinc (Zn), tin (Sn) and/or an alloy thereof. The sliding layer is arranged on the intermediate layer.

According to a preferred embodiment, the substrate is a metallic substrate. Preferably, the metallic substrate is formed of copper, iron, zinc, tin, aluminum, and/or alloys thereof. Preferably, alloys are bronze or brass. More preferably, the metallic substrate is formed of copper, iron and/or an alloy thereof.

According to another preferred embodiment, the substrate is a non-metallic substrate. Preferably, the non-metallic substrate is formed of plastic, glass, oxides, semiconductors and/or ceramics, more preferably the substrate is formed of plastic or ceramics.

In a preferred embodiment, the solid lubricant is selected from the group consisting of sulfides, selenides and/or tellurides. Further preferably, the solid lubricant is selected from the group consisting of WS₂, MoS₂, NbS₂, NbSe₂, TaS₂, MoTe₂, MoSe₂, WTe₂, WSe₂, HfS₂, SnS₂, Bi₂S₃, Sb₂S₃ and/or mixtures thereof.

In another preferred embodiment, the solid lubricant is selected from the group consisting of graphite, graphite oxide, graphite fluoride, phthalocyanine, organic polymers, in particular polytetrafluoroethylene (PTFE) and/or metal complexes derived therefrom.

The sliding layer of the electrical contact must not exceed a maximum layer thickness, as this can have a negative effect on the contact resistance. Preferably, the sliding layer has a layer thickness of at most 3 μm, preferably a layer thickness of at most 2 μm, more preferably a layer thickness of at most 1 μm and even more preferably 0.01 μm-1 μm. The layer thickness is at least 0.001 μm, preferably at least 0.01 μm, more preferably at least 0.05 μm and even more preferably at least 0.1 μm. In a very particularly advantageous embodiment, the layer thickness of the sliding layer is from 10 nm to 500 nm, preferably from 50 nm to 500 nm.

In an advantageous embodiment, the average particle size (d50) of the solid lubricant is from 1 nm-100 μm, preferably from 50 nm-75 μm, more preferably from 100 nm-50 μm, even more preferably from 500 nm-35 μm, and even more preferably from 1 μm-20 μm.

Further preferably, the solid lubricant contains, preferably consists of, a finely dispersed solid component with an average particle size (d50) of 1 nm-100 μm, preferably with an average particle size (d50) of 10 nm-100 μm, more preferably with an average particle size (d50) of 50 nm-75 μm, even more preferably with an average particle size (d50) of 100 nm-50 μm, even more preferably with an average particle size (d50) of 500 nm-35 μm, and even more preferably with an average particle size (d50) of 1 μm-20 μm.

Further preferably, the particle thickness of the solid lubricant is from 1 nm-4 μm, preferably 10 nm-4 μm, more preferably from 100 nm-4 μm and more preferably from 100 nm to 3 μm.

The sliding layer was not produced by means of electrochemical deposition.

In principle, it is envisaged that the sliding layer completely covers the underlying substrate or the underlying intermediate layer in order to achieve the explained tribological advantages. According to a preferred embodiment, the sliding layer completely covers the underlying substrate or the underlying intermediate layer.

However, it is also possible to produce sliding layers that only partially cover the substrate or intermediate layer underneath in order to influence the properties of the surface as a result. By selectively controlling the application parameters, it is possible to form uncoated areas and still achieve an improvement in the tribological properties. In this way, for example, the favorable properties of an intermediate layer, especially its low contact resistance, can be retained. According to a preferred embodiment, the sliding layer at least partially covers the substrate or intermediate layer arranged thereunder. Preferably, the substrate or the intermediate layer is structured; and/or the sliding layer at least partially covering the substrate or the intermediate layer is structured.

Preferably, the coefficient of friction of the electrical contact is in the range of 0.02-0.90, more preferably 0.10-0.87, and more preferably 0.17-0.85.

Preferably, the coefficient of friction remains constant over 1000 mating cycles.

Equally preferably, the contact resistance of the electrical contact is in the range of 0.1-60 mOhm, preferably 0.6-50 mOhm, more preferably 0.7-48.5 mOhm, even more preferably 0.8-40 mOhm, and even more preferably 0.8-35 mOhm.

Preferably, the contact resistance remains constant over 1000 mating cycles.

The solid lubricant forming the sliding layer can preferably be selected from the group consisting of sulfides, selenides, tellurides.

In a particularly advantageous embodiment, the solid lubricant is selected from the group consisting of WS₂, MOS₂, NbS₂, NbSe₂, TaS₂, MoTe₂, MoSe₂, WTe₂, WSe₂, HfS₂, SnS₂, Bi₂S₃, Sb₂S₃ and/or mixtures thereof. Particularly preferred are the sulfides WS₂ and MoS₂, since they have a high affinity for metal surfaces and thus form a strong bond to them.

Tungsten disulfide in particular also has the advantage that the particles have virtually no interaction with one another, so that very thin sliding layers can be produced on the intermediate layer of the electrical contact when tungsten disulfide is used as a solid lubricant.

In a further advantageous embodiment, the solid lubricant may be selected from the group consisting of graphite, graphite oxide, graphite fluoride, phthalocyanine, organic polymers, in particular polytetrafluoroethylene (PTFE), and/or metal complexes derived therefrom.

The present invention also relates to an electrical contact comprising a substrate, the substrate having a metallic and/or metallized surface, and at least one sliding layer disposed on the metallic and/or metallized surface of the substrate, the sliding layer consisting of a solid lubricant, wherein the electrical contact is preferably an electrical plug-in contact.

The above embodiments and modifications also apply to this electrical contact.

In another aspect, the present invention relates to an electrical contact obtainable according to the method of the invention.

In another aspect, the present invention relates to the use of an inventive electrical contact for connectors.

In another aspect, the present invention relates to the use of a solid lubricant to adjust a coefficient of friction of surfaces for electrical contacts.

The solid lubricant is selected from the group consisting of sulfides, selenides and/or tellurides; or the solid lubricant is selected from the group consisting of WS₂, MoS₂, NbS₂, NbSe₂, TaS₂, MoTe₂, MoSe₂, WTe₂, WSe₂, HfS₂, SnS₂, Bi₂S₃, Sb₂S₃ and/or mixtures thereof; or the solid lubricant is selected from the group consisting of graphite, graphite oxide, graphite fluoride, phthalocyanine, organic polymers, in particular polytetrafluoroethylene (PTFE) and/or metal complexes derived therefrom.

### FIGURE DESCRIPTION

The invention and the technical environment are explained in more detail below with reference to the figures. It should be noted that the invention is not intended to be limited by the embodiments shown. In particular, unless explicitly shown otherwise, it is also possible to extract partial aspects of the facts explained in the figures and combine them with other components and findings from the present description and/or figures. In particular, it should be noted that the figures and especially the size relationships shown are only schematic. Identical reference signs designate identical objects, so that explanations from other figures can be used as a supplement if necessary.

It Shows:

FIG. 1 a first embodiment of the electrical contact according to the invention with a sliding layer (6) on a substrate (2);

FIG. 2 a second embodiment of the electrical contact according to the invention with an intermediate layer (5) on a substrate (2) and a sliding layer arranged thereon

FIG. 3 a third embodiment of the electrical contact according to the invention with a first further metal layer (3), an intermediate layer (5) and a sliding layer (6) on a substrate (2);

FIG. 4 a fourth embodiment of the electrical contact according to the invention with a first further metal layer (3), a second further metal layer (4), an intermediate layer (5) and a sliding layer (6) on a substrate (2);

FIG. 5 contact resistance measurements on coated brass sheets with a silver layer (reference sheets; VB1) and coated brass sheets with a silver layer and sliding layer according to the invention applied to it (EB1);

FIG. 6 friction coefficient measurements on coated brass sheets with a silver layer (reference sheets; VB1) and coated brass sheets with a silver layer and sliding layer according to the invention applied to it (EB1);

FIG. 7 contact resistance measurements on coated brass sheets with a tin layer (reference sheets, VB2) and coated brass sheets with a tin layer and sliding layer according to the invention applied to it (EB2 and EB3);

FIG. 8 friction coefficient measurements on coated brass sheets with a tin layer (reference sheets, VB2) and coated brass sheets with a tin layer and sliding layer according to the invention applied to it (EB2 and EB3).

FIG. 1 shows a first embodiment of the electrical contact (1) according to the invention, which comprises a substrate (2) consisting of brass (CuZn39Pb2). A sliding layer (6) was applied to this substrate (2). To produce the electrical contact (1), the sliding layer (6) was applied to the metallic surface of the substrate (2) by rubbing tungsten disulfide particles with a cellulose cloth.

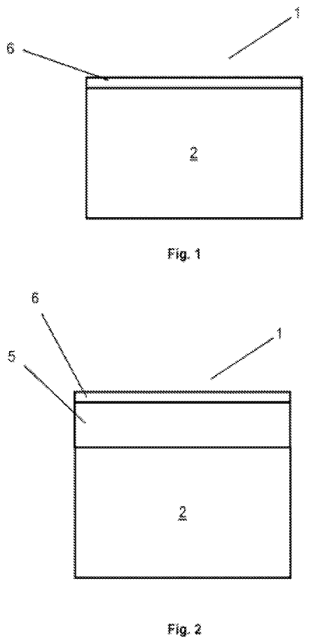

FIG. 2 shows a second embodiment of the electrical contact (1) according to the invention, which comprises a substrate (2), which in this case consists of brass (CuZn39Pb2), as well as an intermediate layer (5) and a sliding layer (6), which was applied to the intermediate layer (5). To produce the electrical contact (1), a layer of pure silver (5) with a layer thickness of 5 um was first applied to the metallic surface of the substrate (2) by electroplating, so that the intermediate layer (5) consisting of silver was formed. Then the sliding layer (6) was applied to the intermediate layer (5) by rubbing tungsten disulfide particles onto it with a cellulose cloth, which was visible in the form of a discoloration of the underlying silver layer constituting the intermediate layer (5).

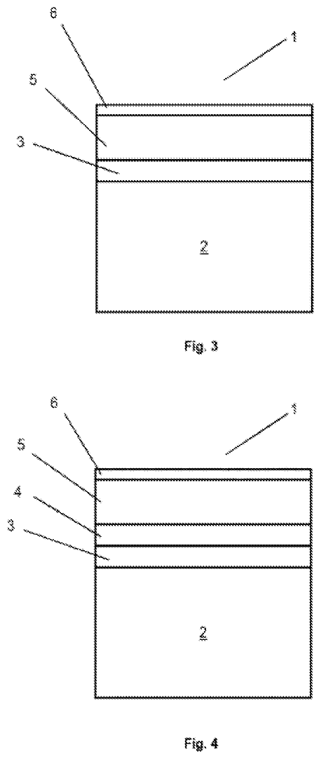

FIG. 3 shows a third embodiment of the electrical contact (1) according to the invention, which comprises a substrate (2), which is presently made of brass (CuZn39Pb2), as well as a first further metal layer (3), an intermediate layer (5) and a sliding layer (6), which was applied to the intermediate layer (5). To produce the electrical contact (1), a layer of copper, which constitutes the first further metal layer (3), was first applied to the brass substrate (2) by electroplating with a layer thickness of 2 μm. Then a layer of pure silver (5) with a layer thickness of 5 μm was electroplated onto the metallic surface of the substrate (2) to form the intermediate layer (5) consisting of silver. Then the sliding layer (6) was applied to the intermediate layer (5) by rubbing tungsten disulfide particles with a cellulose cloth, which was visible in the form of a discoloration of the underlying silver layer constituting the intermediate layer (5).

FIG. 4 shows a fourth embodiment of the electrical contact (1) according to the invention, which comprises a substrate (2), which in this case consists of brass (CuZn39Pb2), as well as a first further metal layer (3), a second further metal layer (4), an intermediate layer (5) and a sliding layer (6), which was applied to the intermediate layer (5). To produce the electrical contact (1), a layer of copper, which constitutes the first further metal layer (3), was first applied to the brass substrate (2) by electroplating with a layer thickness of 2 μm. Then a layer of pure nickel, representing the second further metal layer (4), was electroplated with a layer thickness of 2 μm on the copper layer (3) and then a layer of pure tin, representing the intermediate layer (5), was electroplated with a layer thickness of 5 μm. After this, the sliding layer (6) was applied to the intermediate layer (5) by rubbing tungsten disulfide particles onto the intermediate layer with a cellulose cloth which is visible in form of a discoloration of the underlying tin layer (5).

### LIST OF REFERENCE SIGNS

1 electrical contact
2 substrate
3 first further metal layer
4 second further metal layer
5 intermediate layer
6 sliding layer

### EXAMPLES

### Embodiment Example 1

For example 1, brass sheets (material: CuZn39Pb2) from Metaq GmbH measuring 75 mm×17 mm×1 mm and bronze balls (material: CuSn6) from KUGELPOMPEL HSI-Solutions GmbH with a diameter of 3 mm were used and electroplated. For this purpose, the brass sheets as well as the bronze balls were first copper-plated and then coated with a pure silver layer. Between each step, they were thoroughly rinsed with water.

Electroplating of the brass sheets as well as the bronze balls was carried out according to the procedures described in DE 10 2018 005 352 and DE 10 2018 005 348.

Following electroplating, the sliding layer was applied.

A portion of the coated brass sheets was set aside as a reference, comparative Example 1 (VB1).

The other part was coated with a sliding layer, inventive example 1 (EB1).

Application of the sliding layer: For this purpose, tungsten disulfide particles (WS₂, manufacturer Tribotecc GmbH, Vienna) with an average particle size of d50=3 μm and d90=8 μm were applied by rubbing with a cellulose cloth.

The bronze spheres were coated in the same way as the barrels, first with a 2 μm thick copper layer and then with a 5 μm thick silver layer.

Wear Test

For the wear test, the coated brass plates, EB1 and VB1, were installed in a test rig to simulate mating cycles and rubbed with the coated bronze balls. A weight force of 1.0 N was applied to the ball. This rubbed with the selected force over a distance of 3 mm at a frequency of 1 Hz over the coated brass sheet. This was repeated for 1000 cycles. During the experiment, the frictional force was measured using an U9C load cell (HBM Company). In addition, after each cycle, the contact resistance is measured at the contact between the coated brass sheet and the ball. The contact resistance is measured using the four-wire method with a 2750/E digital multimeter (Keithley Company).

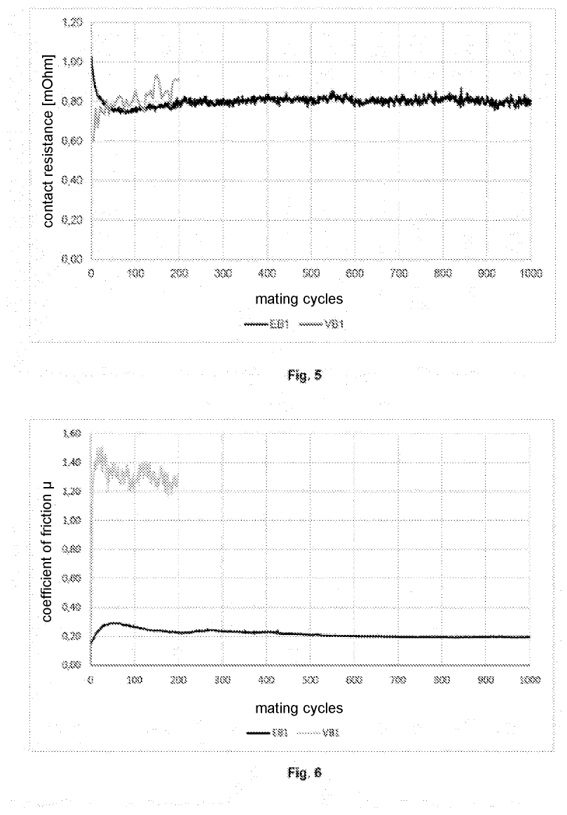

FIG. 5 shows the results of the contact resistance measurement. For the brass sheets coated according to the invention, EB1, the contact resistance remained very stable in the range of 0.8 mOhm after more than 1000 mating cycles, whereas the reference sheets, VB1, showed slightly higher contact resistance values. Furthermore, it was shown that the wear could be significantly reduced by the treatment with the tungsten disulfide particles. As can be seen from FIG. 5, it was possible to carry out more than 1000 mating cycles with the brass sheets coated according to the invention (EB1), whereas the untreated brass sheets (VB1) showed severe wear after only 200 mating cycles, which manifested itself in the form of partial wear. The test was therefore terminated after 200 mating cycles.

Furthermore, a significant reduction in the coefficient of friction was achieved by treatment with tungsten disulfide (see FIG. 6). The reference sheets (VB1) showed a coefficient of friction of 1.2, whereas the brass sheets coated according to the invention (EB1) showed a coefficient of friction in the range of 0.2-0.3. Furthermore, it was found that the coefficient of friction remained constant over 1000 mating cycles.

### Embodiment Example 2

For example 2, brass sheets (material: CuZn39Pb2; F49 (hard)) from Metaq GmbH with dimensions of 75 mm×17 mm×1 mm and bronze balls (material: CuSn6) from KUGELPOMPEL HSI-Solutions GmbH with a diameter of 3 mm were used and electroplated. For this purpose, the brass sheets as well as the bronze balls were first copper-plated and then coated with an intermediate layer of nickel and tin. Between each step, they were thoroughly rinsed with water.

Electroplating of brass sheets as well as bronze balls included the following steps: Degreasing of the substrates, etching of copper with bath of sulfuric acid copper activation free of complexing agents, and treatment with bright copper bath were carried out according to the procedures described in DE 10 2018 005 352 and DE 10 2018 005 348.

Nickel plating was then carried out in a nickel bath with a Watts nickel electrolyte (HSO Ni 110; manufacturer: HSO Herbert Schmidt GmbH & Co. KG, Solingen) according to known procedures.

Then, for the tin layer, a matte tin electrolyte (SLOTOTIN 40; manufacturer: Dr. Ing. Max Schlötter GmbH & Co. KG, Geislingen), which contained tin(I1)methanesulfonate as tin salt, was deposited according to known procedures.

A portion of the coated brass sheets was set aside as a reference, comparative Example 2 (VB2).

The other part was coated with a sliding layer, inventive example 2 (EB2) and inventive example 3 (EB3).

Application of the sliding layer: For this purpose, tungsten disulfide particles (WS₂, manufacturer Tribotecc GmbH, Vienna) with an average particle size of d50=3 μm and d90=8 μm were applied by rubbing with a cellulose cloth. In the present embodiment, the amounts of tungsten disulfide particles were varied so that two different layer thicknesses, EB2 and EB3, were produced and analyzed.

The bronze balls were coated in the same way as the barrels, first with a 2 μm thick copper layer, then with a 2 μm thick nickel layer and finally with a 5 μm thick tin layer.

Wear Test

For the wear test, the coated brass sheets, EB2, EB3 and VB2, were installed in a test rig to simulate mating cycles and rubbed with the coated bronze balls. A weight force of 1.0 N was applied to the ball. This rubbed with the selected force over a distance of 3 mm at a frequency of 1 Hz across the coated brass sheet. This was repeated for 50 cycles. During the experiment, the frictional force was measured using an U9C load cell (HBM Company). In addition, after each cycle, the contact resistance is measured at the contact between the coated brass sheet and the ball. The contact resistance is measured using the four-wire method with a 2750/E digital multimeter (Keithley Company).

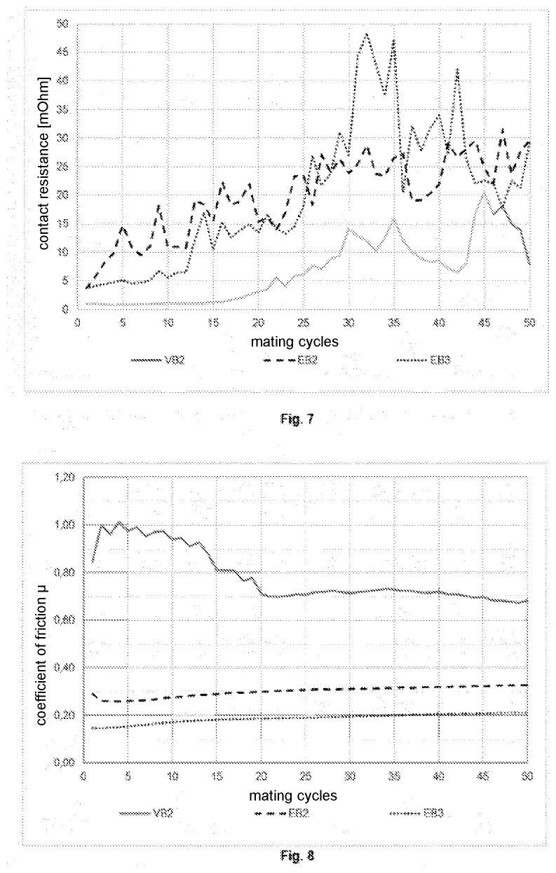

FIG. 7 shows the results from the measurement of the contact resistance. For the brass sheets coated according to the invention, the contact resistance for the samples with a higher amount of tungsten disulfide (EB3) increased from 5 mOhm to 50 mOhm after more than 50 mating cycles. For the samples with a lower amount of tungsten disulfide (EB2), the contact resistance increased from 5 mOhm to 30 mOhm after more than 50 mating cycles.

FIG. 8 summarizes the results from the friction coefficient measurements. Depending on the amount of tungsten disulfide, a coefficient of friction of 0.15-0.3 was determined for samples EB2 and EB3. A coefficient of friction of 0.7-0.8 was observed for the specimen without a sliding layer (VB2).

Surface determination EB1, EB2 and EB3 with EDX-REM

The chemical composition of the near-surface region was determined semiquantitatively by energy dispersive X-ray spectroscopy. For this purpose, measurements were performed on the samples with an X-Flash Detector 410-M (Bruker AXS Microanalysis GmbH), which is installed in an electron microscope JSM-6610 LV (manufacturer: JEOL), with excitation voltages of 10 kV as well as 20 kV. In each case, an area of about 1 mm² was analyzed in the vicinity of those areas used to determine the contact resistance and the coefficient of friction. Each area was analyzed with both excitation voltage settings.

The evaluation of the measurements was performed with the program Esprit (Bruker).

The measurements are individual measurements of areas with an area of 1 mm² each. The measurements were made in the immediate vicinity of the wear marks resulting from the mating cycle tests.

TABLE 1

| | EB1 | | EB2 | | EB3 | |
|---|---|---|---|---|---|---|
| Example | (Ag-WS2) | | (Sn-WS2) | | (Sn-WS2) | |
| Acceleration | 20 | 10 | 20 | 10 | 20 | 10 |
| voltage (kV) | | | | | | |
| Electron | 1.0 | 0.3 | 1.4 | 0.4 | 1.3 | 0.4 |
| interaction | | | | | | |
| depth | | | | | | |
| of analysis | | | | | | |
| (calculated) | | | | | | |
| (μm) | | | | | | |
| Ag (wt %) | 99.70 | 99.31 | — | — | — | — |
| Sn (wt %) | — | — | 99.22 | 96.14 | 95.56 | 85.15 |
| W (wt %) | 0.00 | 0.46 | 0.38 | 3.02 | 2.89 | 10.11 |
| S (wt %) | 0.30 | 0.23 | 0.40 | 0.84 | 1.55 | 4.74 |

As shown in Table 1, by varying the accelerating voltage of the electron beam, the electron interaction depth was varied. For the analyses with 10 kV accelerating voltage, the electron interaction depth is lower and the resulting tungsten and sulfur contents are higher, respectively, because these elements are located on the surface, i.e., in the sliding layer. Since the WS₂ particles are only on the surface, the EDX analyses show higher solid lubricant contents at lower excitation voltage, since only the uppermost regions are analytically detected here. In contrast, the analyses with higher excitation voltage and thus more extended interaction depth include a larger proportion of the deeper sections of the intermediate layers that are free of solid lubricant particles, which means that the solid lubricant content is correspondingly lower. The measurements confirm that the solid lubricants are present in higher concentrations in the near-surface region.

1. Method for manufacturing an electrical contact, comprising the steps of
a) providing a substrate, the substrate having a metallic and/or metallized surface; and
b) applying a sliding layer (6) to the metallic and/or metallized surface of the substrate (2),
wherein the sliding layer (6) is formed by mechanical rubbing, polishing on and/or buffing a solid lubricant; or
wherein the sliding layer (6) is applied by sputtering a solid lubricant; or
wherein the sliding layer (6) is applied by spraying a solid lubricant using a carrier gas; or
wherein the sliding layer (6) is applied by applying a solid lubricant by means of a drum washer; and
wherein the sliding layer (6) has a layer thickness of 0.001 μm-4 μm.

2. Method according to claim 1, wherein in step b) the solid lubricant is applied in particulate form.

3. Method according to claim 1, wherein the substrate (2) comprises an intermediate layer (5), and wherein the sliding layer is applied to the intermediate layer (5).

4. Method according to claim 3, wherein the substrate (2) comprises at least one further metal layer (3), wherein the at least one further metal layer (3) is arranged between the substrate (2) and the intermediate layer (5), and/or
wherein the substrate (2) comprises at least two further metal layers (3, 4), wherein the at least two further metal layers (3, 4) are arranged between the substrate (2) and the intermediate layer (5), and/or wherein the intermediate layer (5) is a tin or silver layer.

5. Method according to claim 1, wherein step a) comprises the following steps:
providing a substrate (2) and applying an intermediate layer (5); or
providing a substrate (2), applying at least one further metal layer (3), and subsequently applying an intermediate layer (5); or
providing a substrate (2), applying at least three further metal layers and then applying an intermediate layer (5).

6. Electrical contact comprising a substrate (2),
the substrate (2) having a metallic and/or metallized surface, and at least one sliding layer (6) which is arranged on the metallic and/or metallized surface of the substrate (2) and consists of a solid lubricant, the sliding layer (6) having a layer thickness of 0.001 μm-4 μm.

7. Electrical contact according to claim 6,
wherein the substrate (2) has an intermediate layer (5) disposed on the metallic and/or metallized surface of the substrate (2), and wherein the sliding layer (6) is disposed on the intermediate layer (5); or
wherein the substrate (2) has at least one further metal layer (3) arranged on the metallic and/or metallized surface of the substrate (2), and wherein an intermediate layer (5) is arranged on the at least one further metal layer (3), the sliding layer (6) being arranged on the intermediate layer (5).

8. Electrical contact according to claim 6,
wherein the substrate (2) has at least one first further metal layer (3) arranged on the metallic and/or metallized surface of the substrate (2), wherein a and wherein an intermediate layer (5) is arranged on the at least second further metal layer (4), and wherein the sliding layer (6) is arranged on the intermediate layer (5).

9. Electrical contact according to claim 6,
wherein the substrate is formed of copper, iron, zinc, tin, aluminum and/or an alloy thereof; or
where the substrate is made of plastic or ceramic.

10. Electrical contact according to claim 6;
wherein the solid lubricant is selected from the group consisting of sulfides, selenides and tellurides; or
wherein the solid lubricant is selected from the group consisting of WS₂, MoS₂, NbS₂, NbSe₂, TaS₂, MoTe₂, MoSe₂, WTe₂, WSe₂, HfS₂, SnS₂, Bi₂S₃, Sb₂S₃ and mixtures thereof.

11. Electrical contact according to claim 6;
wherein the solid lubricant is selected from the group consisting of graphite, graphite oxide, graphite fluoride, phthalocyanine, organic polymers, polytetrafluoroethylene (PTFE), and metal complexes derived therefrom.

12. Electrical contact according to claim 6,
wherein the sliding layer (6) has a layer thickness of at most 3 μm; and/or
wherein the solid lubricant is in particulate form; and/or
wherein the solid lubricant comprises a finely-dispersed solid component having an average particle size (d50) of 1 nm-100 μm.

13. Electrical contact according to claim 6,
wherein the sliding layer (6) completely covers the underlying substrate or the underlying intermediate layer (5); or
wherein the sliding layer (6) at least partially covers the substrate arranged thereunder or the intermediate layer (5) arranged thereunder.

14. Electrical contact of claim 13,
wherein the substrate or the intermediate layer (5) is structured; and/or
wherein the sliding layer (6) at least partially covers the substrate or the intermediate layer (5) is structured.

15. Electrical contact according to claim 6,
wherein the coefficient of friction of the electrical contact is in the range of 0.02-0.90; and/or
wherein the coefficient of friction remains constant over 1000 mating cycles; and/or
wherein the contact resistance of the electrical contact is in the range of 0.1-60 mOhm; and/or
wherein the contact resistance remains constant over 1000 mating cycles.

16. Electrical contact obtainable by the method according to claim 1.

17. A connector comprising the electrical contact of claim 6.

18. A method for adjusting a coefficient of friction of surfaces of an electrical contacts, comprising using a solid lubricant with the electrical contact, wherein the solid lubricant is selected from the group consisting of sulfides, selenides and tellurides; or wherein the solid lubricant is selected from the group consisting of WS₂, MoS₂, NbS₂, NbSe₂, TaS₂, MoTe₂, MoSe₂, WTe₂, WSe₂, HfS₂, SnS₂, Bi₂S₃, Sb₂S₃ and mixtures thereof; or wherein the solid lubricant is selected from the group consisting of graphite, graphite oxide, graphite fluoride, phthalocyanine, organic polymers, polytetrafluoroethylene (PTFE), and metal complexes derived therefrom.

19. The method of claim 4, wherein the at least one first further metal layer (3) is formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and an alloy thereof.

20. The electrical contact of claim 8, wherein the at least one first further metal layer (3) is formed from one of the metals selected from the group comprising gold (Au), copper (Cu), nickel (Ni), palladium (Pd), platinum (Pt), rhodium (Rh), ruthenium (Ru), silver (Ag), zinc (Zn), tin (Sn) and an alloy thereof.
